(19) United States
(12) Patent Application Publication
(10) Pub. No.: US 2023/0160974 A1
(43) Pub. Date: May 25, 2023

(54) DEVICE AND METHOD FOR DETECTING A SURGE ARRESTER RESISTIVE LEAKAGE CURRENT TO REDUCE COMPUTATIONAL LOAD

(71) Applicant: SURGE TECH CO., LTD, Daejeon (KR)

(72) Inventors: Song yop HAHN, Seoul (KR); Kwang Ho LEE, Okcheon-gun (KR)

(21) Appl. No.: 15/734,236

(22) PCT Filed: Jul. 17, 2020
(86) PCT No.: PCT/KR2020/009446

§ 371 Date: Dec. 2, 2020

(30) Foreign Application Priority Data
Jul. 17, 2020 (KR) 10-2020-0088685

(51) Int. Cl. G01R 31/52

(52) U.S. Cl. CPC G01R 31/52

(57) ABSTRACT

The present invention relates to a device and method for detecting a surge arrester resistive leakage current for reducing the computational load, which may significantly reduce the computational load as the Fourier transform process need not be repeated in the process of searching to match a section to be Fourier transformed to a section in-phase with AC voltage to extract the resistive leakage current component from the Fourier series of surge arrester leakage current and enables real-time detection of the resistive leakage current by shortening the section searching process of one-period leakage current by searching for the section of one-period leakage current, which is to be initially Fourier-transformed, based on the characteristic pattern that it is repeatedly generated by application of an AC voltage. The present invention is implemented by a leakage current detection unit 10 detecting a leakage current in a surge arrester 1, a reference point search unit 20 of selecting a time when the leakage current has a highest left-right symmetry, as a reference point, a Fourier transform unit 30 obtaining a Fourier series for the one-period leakage current starting at the reference point, and a resistive leakage current extraction unit 40 correcting the reference point so that a characteristic pattern of the surge arrester resistive leakage current is shown in the sum the sine terms of the Fourier series.

### TECHNICAL FIELD

The present invention relates to a device and method for detecting a surge arrester resistive leakage current for reducing the computational load, which may significantly reduce the computational load as the Fourier transform process need not be repeated in the process of searching to match a section to be Fourier transformed to a section in-phase with AC voltage to extract the resistive leakage current component from the Fourier series of surge arrester leakage current and enables real-time detection of the resistive leakage current by shortening the section searching process of one-period leakage current by searching for the section of one-period leakage current, which is to be initially Fourier-transformed, based on the characteristic pattern that it is repeatedly generated by application of an AC voltage.

### BACKGROUND ART

Surge arresters are installed to protect electric devices, such as transformers and circuit breakers, connected to the power system from abnormal voltages due to lightning strikes and switching surges. Recently, metal-oxide surge arresters (MOSA) are widely used.

The metal-oxide surge arrester is modeled as a circuit in which a non-linear resistance is connected in parallel to a capacitance, and the leakage current flowing when a grid voltage is applied may be interpreted as a composite current of the resistive leakage current through the non-linear resistance and the capacitive leakage current through the capacitance.

When the surge arrester deteriorates, the capacitance is almost constant and, thus, the capacitive leakage current hardly fluctuates. With the progress of the deterioration, however, the non-linear resistance gradually decreases and the resistive leakage current increases significantly. Therefore, a most preferable way to accurately determine the deterioration state of the surge arrester is to extract the resistive leakage current from the leakage current flowing through the surge arrester and determine the deterioration state.

According to Korean Patent No. 10-2068028, by the inventors of the present invention, it is possible to extract the resistive leakage current by detecting only the surge arrester leakage current without detecting the voltage, using the fact that the characteristic patterns of the surge arrester leakage current and the resistive leakage current are shown before and after the time when the voltage is 0 V, and the fact that the resistive leakage current component may be obtained by extracting the sine term from the Fourier series of the leakage current of the surge arrester for one period that starts at the time when the voltage is 0 V.

According to Korean Patent No. 10-2068028, since the symmetry of the surge arrester leakage current is highest at the time when the voltage is 0 V, the resistive leakage current may be accurately extracted by selecting the time when the symmetry is the highest as a reference point and then stepwise correcting the reference point until the composite component of the sine term extracted from the Fourier series of the one-period surge arrester leakage current starting at the reference point shows the characteristic pattern of the resistive leakage current.

However, since the technology disclosed in Korean Patent No. 10-2068028 requires a new Fourier series to be obtained each time the reference point is corrected, digital computational processing is burdened. Moreover, even high-order components of the surge arrester leakage current need to be detected and, to accurately extract the resistive leakage current from the surge arrester leakage current, the reference point is required to be accurately corrected sample-by-sample. To this end, the sampling rate needs to be increased, and the number of samples of one period increases accordingly. Further, the memory and computational load for obtaining the Fourier series increases. The increase in memory and computational load renders it difficult to detect the resistive leakage current in real time and diagnose degradation.

Further, since the technology disclosed in Korean Patent No. 10-2068028 selects a reference point according to the symmetry of the leakage current of the surge arrester into which noise has been introduced, a time when the voltage is significantly deviated from the time when the voltage is 0 V may be selected as the reference point, and the number of times of the correction may be thus increased, and more loads may be posed on the computation.

### PRIOR TECHNICAL DOCUMENTS

### Patent Documents

(Patent Document 1) KR 10-2068028 B1 2020.01.14.

### DETAILED DESCRIPTION OF THE INVENTION

### Technical Problem

Thus, the present invention aims to provide a device and method for detecting a surge arrester resistive leakage current, which may significantly reduce the computational load in the digital area by estimating as close to the time when the voltage is 0 V a time as possible upon estimating the time when the voltage is 0 V according to the pattern of the detected surge arrester leakage current and, upon correcting the period which is subject to a Fourier-transform until the characteristic pattern of the resistive leakage current is shown in the sine term of the Fourier series of the surge arrester leakage current, calculating the Fourier series without performing a Fourier-transform.

### Technical Solution

To achieve the above objects, according to the present invention, a method for detecting a surge arrester resistive leakage current comprises a leakage current detection step S10 of detecting a total leakage current I_{T} flowing through a surge arrester 1 to which a periodic AC voltage is applied, as a digital data value, a reference point search step S20 of selecting a time when the total leakage current I_{T} has a highest left-right symmetry, as a reference point, a Fourier transform step S30 of obtaining a Fourier series by Fourier-transforming the total leakage current I_{T} during one period starting at the reference point, a reference point verification step S40 of verifying the reference point depending on whether a characteristic pattern of a resistive leakage current I_{R} according to a non-linear resistive characteristic of the surge arrester 1 is shown in a sum of sine terms of the Fourier series, a reference point correction step S50 of reperforming the reference point verification step S40 by correcting the reference point, if the characteristic pattern is not shown in the reference point verification step S40, and obtaining a Fourier series of the one-period total leakage current I_{T} varying according to reference point correction from an equation resultant from reference point time-shifting a Fourier series before the reference point correction, and a resistive leakage current extracting step S60 of setting the sum of the sine terms of the Fourier series as the resistive leakage current I_{R} if the characteristic pattern is shown in the reference point verification step S40.

According to an embodiment, the reference point correction step S50 sets a sine term coefficient of the Fourier series according to the reference point time shift as

$$- {a}_{m} sin ( m \frac{2 π}{N} Δ n ) + {b}_{m} cos ( m \frac{2 π}{N} Δ n )$$

and a cosine term coefficient as

$${a}_{m} cos ( m \frac{2 π}{N} Δ n ) + {b}_{m} sin ( m \frac{2 π}{N} Δ n ) ,$$

wherein m is an order of the Fourier coefficient, aₘ is an mth-order cosine term Fourier coefficient of the Fourier series before time shifting, bₘ is an m-order sine term Fourier coefficient of the Fourier series before time shifting, N is a number of samples in one period, and Δn is a sample interval resultant from time-shifting the reference point.

To achieve the above objects, according to the present invention, a device for detecting a surge arrester resistive leakage current comprises a leakage current detection unit 10 sampling a total leakage current I_{T} flowing through a surge arrester 1 to which a periodic AC voltage is applied, and detecting a digital data value, a reference point search unit 20 selecting a time when the total leakage current I_{T} has a highest left-right symmetry, as a reference point, a Fourier transform unit 30 obtaining a Fourier series by Fourier-transforming the total leakage current I_{T} during one period starting at the reference point, and a resistive leakage current extraction unit 40 correcting the reference point until a characteristic pattern of a resistive leakage current I_{R} according to a non-linear resistive characteristic of the surge arrester 1 is shown in a sum of sine terms of the Fourier series, obtaining the Fourier series of the one-period total leakage current I_{T} varying according to the reference point correction from a Fourier series before the reference point correction, and setting the sum of the sine terms of the Fourier series, where the characteristic pattern of the resistive leakage current I_{R} is shown, as the resistive leakage current I_{R}.

### Advantageous Effects

As configured as above, the present invention may perform a Fourier-transform only once during the course of modifying the one-period surge arrester leakage current period where development as a Fourier series is to be performed to obtain the resistive leakage current using the Fourier series of the surge arrester leakage current and obtain it from the equation resultant from time-shifting the Fourier series according to the period modification. Thus, as compared with the method of repeating a Fourier-transform according to the period modification, the present invention may significantly reduce computational load and may thus enable real-time detection of the resistive leakage current and diagnosis of the deterioration state of the surge arrester.

According to an embodiment of the present invention, even upon detecting the period of the one-period surge arrester leakage current to be Fourier-transformed, a result of obtaining at a plurality of times based on periodicity may be reflected. Thus, the period modification process may be reduced, and the computational load may be further decreased.

### BRIEF DESCRIPTION OF DRAWINGS

FIG. 1 is a block diagram illustrating a device for detecting a surge arrester resistive leakage current according to an embodiment of the present invention;

FIG. 2 is a flowchart illustrating a device for detecting a surge arrester resistive leakage current according to an embodiment of the present invention;

FIG. 3 is a view illustrating example waveforms of a resistive leakage current I_{R}, a capacitive leakage current I_{C}, and a total leakage current I_{T} flowing through a surge arrester 1 when a periodic AC grid voltage u is applied to the surge arrester 1;

FIG. 4 is a view illustrating a waveform of a total leakage current I_{T} detected by a surge arrester 1; and

FIG. 5 is a view illustrating a waveform of a sine term composite signal of a Fourier series that varies according to a selection position of a reference point.

### DETAILED DESCRIPTION OF EMBODIMENTS

Hereinafter, preferred embodiments of the present invention are described with reference to the accompanying drawings to be easily practiced by one of ordinary skill in the art.

When determined to make the subject matter of the present invention unnecessarily unclear, a detailed description of the known functions or known configuration as disclosed in Korean Patent No. 10-2068028 may be skipped.

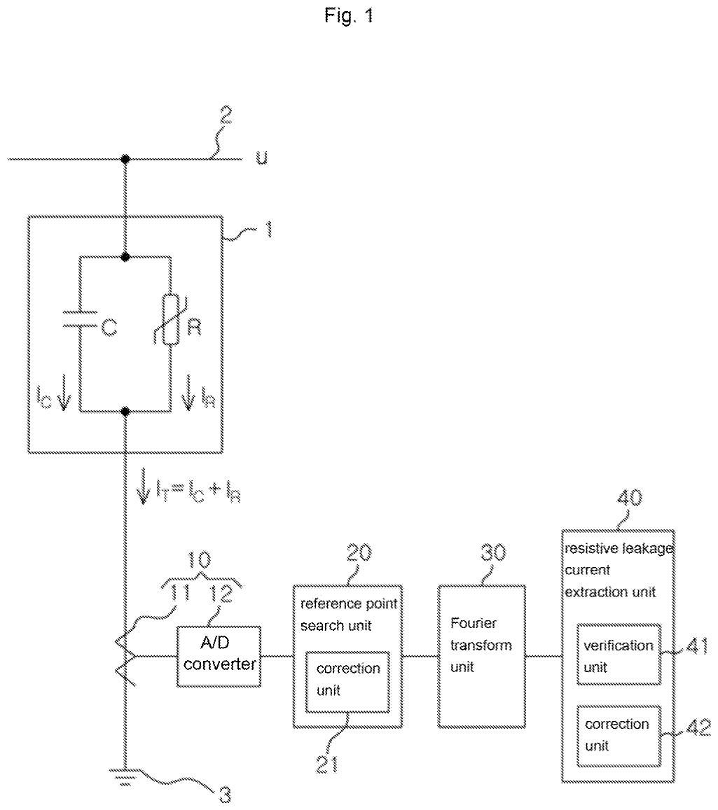

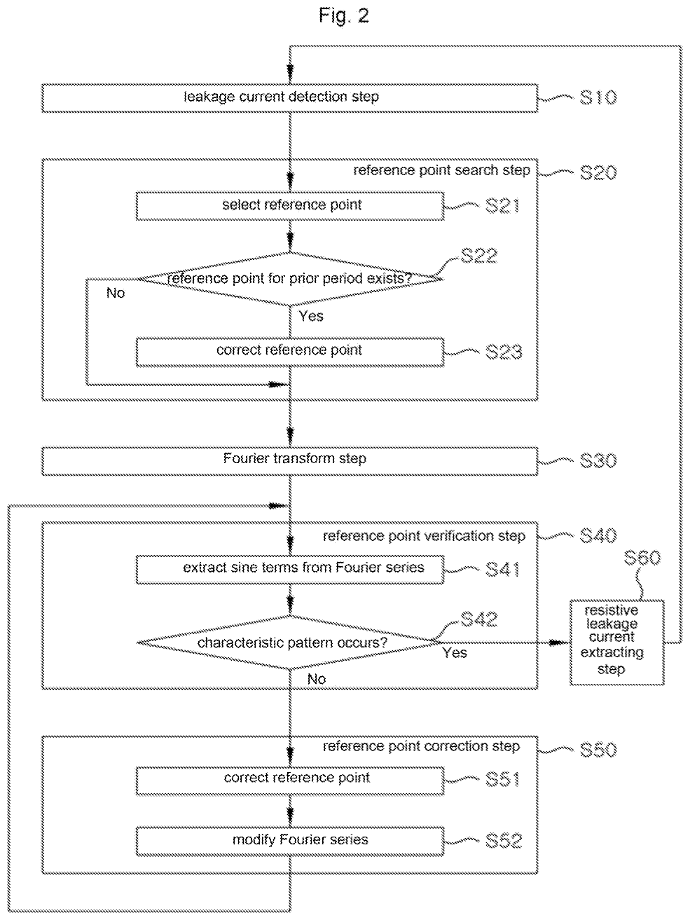

Referring to the block diagram shown in FIG. 1 and the flowchart shown in FIG. 2, a device for detecting a surge arrester resistive leakage current, according to an embodiment of the present invention, includes a leakage current detection unit 10 for performing a leakage current detection step S10, a reference point search unit 20 for performing a reference point search step (S20), a Fourier transform unit 30 for performing a Fourier transform step (S30), and a resistive leakage current extraction unit 40 for performing a reference point verification step (S40), a reference point correction step (S50), and a resistive leakage current extracting step (S60).

The leakage current detection unit 10 detects the current flowing through a surge arrester 1 connected between a grid bus 2 of a power system and a ground line 3 as a digital data value and performs the leakage current detection step (S10). To this end, the leakage current detection unit 10 may include a current transformer 11 that transforms the current flowing through the surge arrester 1 to the ground line 3 as the grid voltage u, which is a periodic alternating current (AC) voltage, is applied through the grid bus 2, into a current within a specific range and outputs the transformed current and an A/D converter 12 that converts the analog current signal output from the current transformer 11 into digital data by sampling the analog current signal at a predetermined sample period.

The surge arrester 1 may be equivalent to a circuit in which a capacitance C and a non-linear resistance R are connected in parallel, and may be, e.g., a metal-oxide surge arrester (MOSA). Accordingly, the current flowing through the surge arrester 1 and detectable by the leakage current detection unit 10 may be regarded as a composite current of a capacitive leakage current I_{C} flowing through the capacitance C and a resistive leakage current I_{R} flowing through the non-linear resistance R, based on a modeling of the surge arrester 1. In the following description, the composite current of the capacitive leakage current I_{C} and the resistive leakage current I_{R} is referred to as a total leakage current I_{T}.

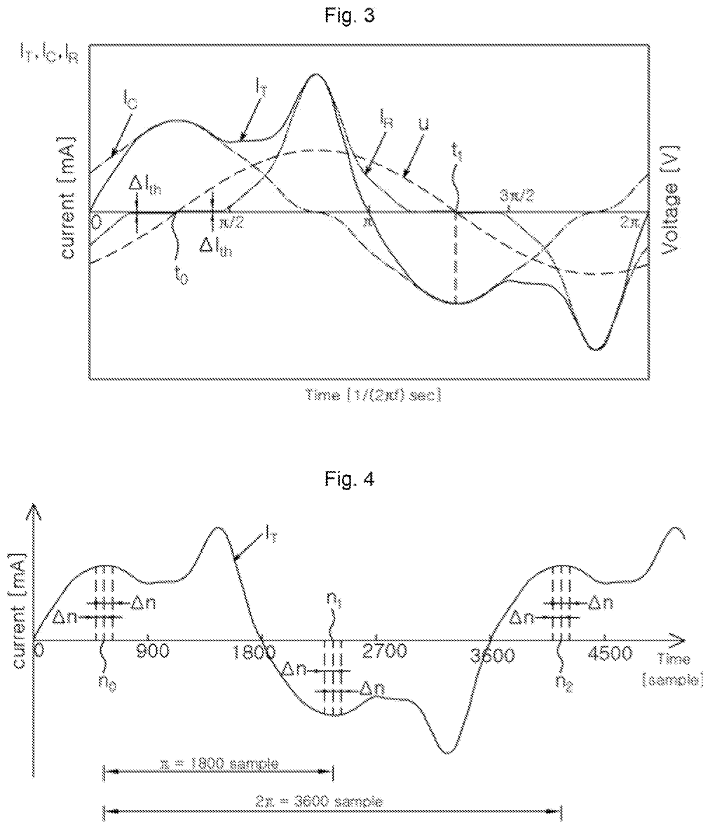

The grid voltage u is a periodic AC voltage having a grid frequency of 60 Hz in the case of Korea, and when applied to the surge arrester 1, the leakage current illustrated in FIG. 3 may flow.

FIG. 3 is a graph illustrating a waveform of the one-period total leakage current I_{T} detected from the surge arrester 1, a waveform of the capacitive leakage current I_{C} included in the one-period total leakage current I_{T}, and the resistive leakage current I_{R} included in the one-period total leakage current I_{T}. As can be seen in FIG. 3, the resistive leakage current I_{R} is a current in phase with the grid voltage u, and the capacitive leakage current I_{C} is a leading current whose phase is 90 degrees ahead of the grid voltage u.

The resistive leakage current I_{R} is less than a current ΔIₜₕ, which is tiny enough to be neglectable, in the period where the grid voltage u is a predetermined value or less, due to the characteristics of the non-linear resistance R and, when the grid voltage u exceeds the predetermined value, the resistive leakage current I_{R} rapidly increases according to the magnitude of the grid voltage u. Accordingly, the total leakage current I_{T} shows a characteristic pattern in which symmetry is the highest at the times (t0 and t1) when the grid voltage u is 0 V, and the resistive leakage current I_{R} shows a characteristic pattern in which it becomes below the tiny current ΔIₜₕ in the periods before and after the times (t0 and t1) when the grid voltage u is 0 V.

The surge arrester 1 has a low limiting voltage and excellent discharge characteristics due to the characteristics of the non-linear resistance R. However, as the surge arrester 1 deteriorates, the resistive leakage current gradually increases and the period, in which the tiny current ΔIₜₕ or less, flows narrows, it may lose its performance. However, as the characteristics of the capacitive load C do not change significantly, it is necessary to diagnose the deterioration by detecting the resistive leakage current I_{R}.

To that end the reference point search unit 20, the Fourier transform unit 30, and the resistive leakage current extraction unit 40 search the time when the grid voltage u is 0 V using the characteristic pattern of the resistive leakage current I_{R} and the characteristic pattern of the total leakage current I_{T} shown in the periods before and after the time when the voltage is 0 V like disclosed in Korean Patent No. 10-2068028, sets a time when the grid voltage u is 0 V as a start reference point of the period of a one-period total leakage current I_{T} to be developed as Fourier series, and extracts the resistive leakage current I_{R} from the Fourier series of the total leakage current I_{T}.

However, according to the present invention, the excessive computational load, which is a problem with Korean Patent No. 10-2068028, is greatly reduced. To that end, the computational load is significantly reduced by raising the accuracy of searching for a reference point according to the characteristic pattern of the total leakage current I_{T} to thereby correct the reference point, reducing the number of numbers in which the process of obtaining the Fourier series is performed, and calculating the coefficients of the Fourier series that fluctuate according to the correction of the reference point.

The following description focuses primarily on technical features distinct from those disclosed in Korean Patent No. 10-2068028, with the known art in Korean Patent No. 10-2068028 excluded from the description.

The reference point search unit 20 selects a reference point n₀ according to the pattern of the total leakage current I_{T} detected as digital data via the leakage current detection unit 10, as shown in the waveform diagram of FIG. 4 and performs the reference point search step S20.

The waveform diagram of FIG. 4 is a waveform of the total leakage current I_{T} detected using 3,600 samples (the number N of samples is 3,600) during one period.

The reference point n₀ is a time when the grid voltage u is estimated to be 0 V and is selected by searching for a time when the total leakage current I_{T} has the highest left-right symmetry and, as described below, the reference point n₀ is applied as a start point of the one-period total leakage current I_{T} which is to be developed as a Fourier series.

The reference point n₀ may be searched and selected by one of the following three methods.

In a first method, a time when the one-period total leakage current I_{T} has the highest left-right symmetry in a half-period period having a positive (+) value may be searched and selected as the reference point n₀. The left-right symmetry may be evaluated according to the degree of symmetry calculated for the data of a predetermined prior-subsequent period width (Δn) as described in Korean Patent No. 10-2068028. Given the width of the period in which a current not more than the tiny current ΔIₜₕ before and after the time when the grid voltage u is 0 V and the possibility of fluctuation of the period width due to deterioration, the prior-subsequent period width (Δn) may be predetermined as a proper value to prevent it from being erroneously detected as the time corresponding to the peak value of the resistive leakage current I_{R}.

Of course, a time when the highest left-right symmetry is shown in a half-period period having a negative (−) value may be searched and selected as the reference point n₁.

In a second method, any one reference point may be corrected and selected according to the size of the period between the reference point n₀ searched in the positive (+) period of the one-period total leakage current I_{T} and the reference point n₁ searched in the negative (−) period.

As shown in FIG. 4, there is supposed to be a half-period (n) difference between the positive (+) period reference point n₀ and the negative (−) period reference point n₁, but may not be due to influence by noise introduced upon detection, detection errors, and A/D conversion resolution. Thus, the reference point is corrected depending on the difference between the half period (n) and the interval between the two reference points n₀ and n₁. The search time may be reduced by searching for one of the two reference points n₀ and n₁ and then searching the periods before and after the time when the half-period difference is made, for the other reference point.

A specific example for selecting a reference point may be to time-shift, by half period (n), one of the two reference points n₀ and n₁ towards the other reference point and then select the average value as a reference point.

In a third method, the reference point selected by the above-described first or second method may be corrected according to the reference point of the prior one-period total leakage current I_{T}.

To that end, the reference point search unit 20 may include a correction unit 21 that memorizes the reference point applied for the prior one-period total leakage current I_{T} and searches and selects a reference point for the current one-period total leakage current I_{T}.

For example, the reference point applied when the resistive leakage current I_{R} is extracted by the resistive leakage current extraction unit 40 is stored as described below.

The reference point search unit 20 searches for the reference point n_{z} for the current period (S21), identifies whether the reference point n₀ for the prior period is stored (S22) and, if the reference point n₀ for the prior period is stored, activates the correction unit 21 to correct the reference point n₂ (S23).

The correction unit 21 corrects the reference point n₂ for the current period depending on the difference between the searched reference point n_{z} for the current period and the reference point n₀ for the prior period, minus one period (2n). As an example correction method, the reference point n₀ for the prior period is time-shifted by one period (2n) towards the current period, and then, the average of the time-shifted reference point and the reference point n₂ searched in the current period may be selected.

Meanwhile, upon searching for the reference point n_{z} in the total leakage current I_{T} for the current period, a predetermined period from a time which is one period (2n) after the reference point n₀ applied and stored in the prior period is set as a search period, and the reference point n₂ is searched in the search period.

The one-period total leakage current I_{T} which starts from the reference point is varied by the reference point modification or correction. However, as described in Korean Patent No. 10-2068028, an rearranging method may be applied which attaches the prior period to the subsequent period, or the subsequent period to the prior period, for the detected one-period total leakage current I_{T}.

The Fourier transform unit 30 performs the Fourier transform step S30 to Fourier-transform the one-period total leakage current I_{T}, which starts at the reference point selected by the reference point search unit 20, to thereby develop it as a Fourier series as shown in Equation 1 below.

$${I}_{T} ( n ) = {\sum }_{m = 1}^{9} {a}_{m} cos ( m \frac{2 π}{N} Δ n ) + {\sum }_{m = 1}^{9} {b}_{m} sin ( m \frac{2 π}{N} Δ n ) , \\ n = 0 , 1 , 2 , 3 , … , N - 1 \qquad [ Equation 1 ]$$

Here, N is the number of samples of the one-period total leakage current I_{T} and, according to the waveform diagram illustrated in FIG. 4, N is set to 3600. n is the sample number of the total leakage current I_{T}, and m is the order. In general, since the harmonics mixed with the grid voltage u are odd-numbered ones and only up to the ninth harmonic may be considered, as the order expressed by m, only the 1st, 3rd, 5th, 7th, and 9th order including the 1st order of the fundamental wave may be considered.

aₘ is the Fourier coefficient of the mth-order cosine term, and bₘ is the Fourier coefficient of the mth-order sine term, and are obtained by Equation 2 below.

$${a}_{m} = \frac{2}{N} {\sum }_{n = 0}^{N - 1} {I}_{T} ( n ) cos ( m \frac{2 π}{N} n ) , m = 1 , 3 , 5 , 7 , 9 \\ {b}_{m} = \frac{2}{N} {\sum }_{n = 0}^{N - 1} {I}_{T} ( n ) sin ( m \frac{2 π}{N} n ) , m = 1 , 3 , 5 , 7 , 9 \qquad [ Equation 2 ]$$

The resistive leakage current extraction unit 40 includes a verification unit 41 that verifies the accuracy of the reference point according to the pattern of the signal composed of the sum of the sine terms in the Fourier series of Equation 1 to thereby perform the reference point verification step S40 and a correction unit 42 that, when the reference point is determined to be incorrect as a result of the verification, corrects the reference point and then allows it to be verified again to thereby perform the reference point correction step S50. The resistive leakage current extraction unit 40 performs the resistive leakage current extracting step S60 that definitely determines that the signal resultant from extracting only sine terms from the Fourier series of the one-period total leakage current I_{T}, which starts at the finally corrected reference point only when the reference point is determined to be accurate as a result of the verification, and summating the extracted sine terms, is the resistive leakage current I_{R}.

The reference point verification step S40 by the verification unit 41 includes extracting the signal composed of the sine terms from the Fourier series of Equation 1 using Equation 3 below (S41) and identifying whether the characteristic pattern of the resistive leakage current I_{R} is shown (S42).

$${I}_{R} ( n ) = {\sum }_{m = 1}^{9} {b}_{m} sin ( m \frac{2 π}{N} n ) , \\ n = 0 , 1 , 2 , 3 , … , N - 1 , \\ m = 1 , 3 , 5 , 7 , 9 \qquad [ Equation 3 ]$$

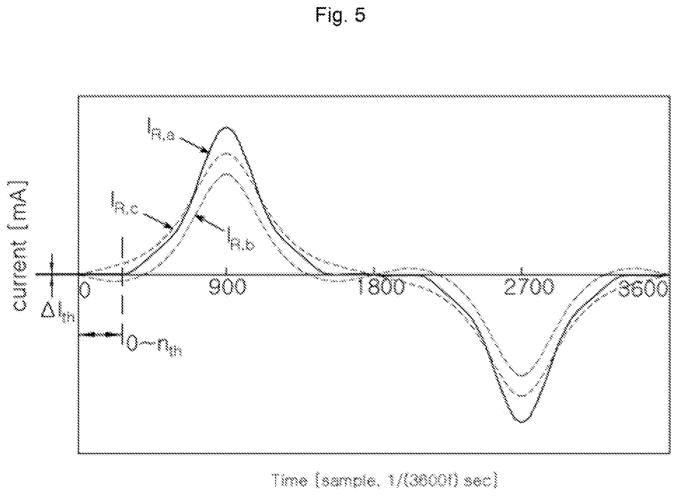

However, as described in Korean Patent No. 10-2068028, the sum of the sine terms expressed by Equation 3 in the Fourier series differs according to the selection position of the reference point as shown in FIG. 5.

In FIG. 5, I_{R,a} is the waveform of the sum of the sine terms obtained when the reference point is selected as the time when the applied voltage u is 0 V and, in the initial period (0 to nth) starting at the reference point, such a characteristic pattern is shown where a current below a neglectable tiny current ΔIₜₕ flows. I_{R,b} is the waveform when a time later than the time when the applied voltage u is 0 V is selected as the reference point, and a section when the current is less than 0 A occurs in the initial period 0 to nth. I_{R,c} is the waveform when a time earlier than the time when the applied voltage u is 0 V is selected as the reference point, and a section when the current is more than the neglectable ΔIₜₕ occurs in the initial period 0 to nth.

The accuracy of the selected reference point is verified depending on whether the characteristic pattern of the resistive leakage current I_{R}, which has a value not more than the tiny current ΔIₜₕ in the initial period 0 to nth is shown in the sum of the sine terms of the Fourier series.

A proper length of the initial period 0 to nth may be determined considering the length of the period when the resistive leakage current I_{R} of the surge arrester 1, which has not be deteriorated, flows in the magnitude not more than the tiny current ΔIₜₕ, as described above in connection with FIG. 3, and may then be used upon verification. For example, the proper length of the initial period 0 to nth may be determined to be a range from 0 to n/6.

Meanwhile, as detailed in Korean Patent No. 10-2068028 and shown in FIG. 5, a plurality of times in the initial period 0 to nth are set and, for verification, the value at the corresponding time may be compared with the tiny current ΔIₜₕ.

The reference point correction step S50 by the correction unit 42 is performed when the characteristic pattern of the resistive leakage current I_{R} is not shown in the sum of the sine terms of the Fourier series as a result of the verification, and corrects the reference point (S51), obtains the Fourier series of the one-period total leakage current I_{T} which varies according to the correction of the reference point (S52), and allows the reference point verification step S40 by the verification unit 41 to be performed again. In other words, the reference point is repeatedly corrected until the characteristic pattern of the resistive leakage current I_{R} is shown in the sum of the sine terms of the Fourier series, and the Fourier coefficients of the Fourier series are modified accordingly.

Here, the method described in Korean Patent No. 10-2068028 may be used to correct the reference point. That is, if a reference point is selected in the positive (+) period, when the current is less than 0 A at, at least any one, of a plurality of times in the initial period 0 to nth, the reference point is stepwise time-shifted to be brought forward until the current is 0 A or more at all of the plurality of times in the initial period 0 to nth and, when the current exceeds the tiny current ΔIₜₕ at all of the plurality of times in the initial period 0 to nth, the reference point is stepwise time-shifted to be put back until the current is 0 A or less at, at least any one, of the plurality of times in the initial period 0 to nth.

In contrast, if a reference point is selected in the negative (−) period, when the current is 0 A or more at, at least any one, of a plurality of times in the initial period 0 to nth, the reference point is stepwise time-shifted to be brought forward until the current is 0 A or less at all of the plurality of times in the initial period 0 to nth and, when the current is less than the tiny current ΔIₜₕ at all of the plurality of times in the initial period 0 to nth, the reference point is stepwise time-shifted to be put back until the current is 0 A or more at, at least any one, of the plurality of times in the initial period 0 to nth. Of course, it is preferable to time-shift at each sample interval.

According to Korean Patent No. 10-2068028, Fourier coefficients are calculated by again Fourier-transforming the one-period total leakage current I_{T} that varies according to the correction of the reference point.

However, according to the present invention, the Fourier coefficients that fluctuate according to the correction of the reference point are calculated by applying the addition theorem of the trigonometric function in an equation resultant from reference point time-shifting the Fourier series before the correction of the reference point correction.

The Fourier coefficients according to the reference point time-shifting may be calculated as follows.

The Fourier series resultant from time-shifting the reference point by Δn may be expressed as in Equation 4 below by time-shifting Equation 1, which is expressed as the Fourier coefficient before time-shifting the reference point.

$$\begin{matrix}{I}_{T} ( n ) = {\sum }_{m = 1}^{9} {a}_{m} cos ( m \frac{2 π}{N} ( n + Δ n ) ) + {\sum }_{m = 1}^{9} {b}_{m} sin ( m \frac{2 π}{N} ( n + Δ n ) ) \\ = {\sum }_{m = 1}^{9} {a}_{m} cos ( m \frac{2 π}{N} n + m \frac{2 π}{N} Δ n ) + \\ {\sum }_{m = 1}^{9} {b}_{m} sin ( m \frac{2 π}{N} n + m \frac{2 π}{N} Δ n )\end{matrix} \qquad [ Equation 4 ]$$

As mentioned above, n is the sample number in order, N is the total number of the samples in one period, and m is the order. However, n is the sample number assigned from the time-shifted reference point.

Referring to Equation 4, the cosine term and the sine term on the right side each are time-shifted and are thus expressed as the terms whose phase has been varied by

$$m \frac{2 π}{N} Δ n ,$$

and may thus be arranged according to the addition theorem of trigonometric functions as shown in Equation 5 below.

$${I}_{T} ( n ) = {\sum }_{m = 1}^{9} {a}_{m} cos ( m \frac{2 π}{N} n ) cos ( m \frac{2 π}{N} Δ n ) - {a}_{m} sin ( m \frac{2 π}{N} n ) sin ( m \frac{2 π}{N} Δ n ) ) + {\sum }_{m = 1}^{9} {b}_{m} sin ( m \frac{2 π}{N} n ) cos ( m \frac{2 π}{N} Δ n ) + {b}_{m} cos ( m \frac{2 π}{N} n ) sin ( m \frac{2 π}{N} Δ n ) ) \qquad [ Equation 5 ]$$

Referring to Equation 5, the cosine term and sine term including the phase angle

$$m \frac{2 π}{N} Δ n$$

according to the time-shifting may be expressed as two trigonometric functions using the trigonometric function of the phase angle as a coefficient value according to the trigonometric addition theorem.

The terms may be arranged in such a way as to sum up the terms having the same trigonometric function and may thus be expressed as the Fourier series equation as shown in Equation 6 below.

$${I}_{T} ( n ) = {\sum }_{m = 1}^{9} {A}_{m} cos ( m \frac{2 π}{N} n ) + {\sum }_{m = 1}^{9} {B}_{m} sin ( m \frac{2 π}{N} n ) \\ {A}_{m} = {a}_{m} cos ( m \frac{2 π}{N} Δ n ) + {b}_{m} sin ( m \frac{2 π}{N} Δ n ) \\ {B}_{m} = - {a}_{m} sin ( m \frac{2 π}{N} Δ n ) + {b}_{m} cos ( m \frac{2 π}{N} Δ n ) \qquad [ Equation 6 ]$$

In Equation 6, aₘ is the Fourier coefficient of the mth-order cosine term of the Fourier series before time shifting the reference point, and bₘ is the Fourier coefficient of the mth-order sine term of the Fourier series before time shifting the reference point. Aₘ is the Fourier coefficient of the mth-order cosine term of the Fourier series after time shifting the reference point, and Bₘ is the Fourier coefficient of the mth-order sine term of the Fourier series after time shifting the reference point.

Referring to Equation 6, the number N of the samples for one period is a value determined by the leakage current detection unit 10, if only time shift Δn is set to a predetermined value,

$$cos ( m \frac{2 π}{N} Δ n ) and sin ( m \frac{2 π}{N} Δ n )$$

in the equation of calculating the Fourier coefficients Am and Bm after the reference point is time-shifted, except for the Fourier coefficients aₘ and bₘ before the reference point is time-shifted become fixed values for each order. Thus, the values of

$$cos ( m \frac{2 π}{N} Δ n ) and sin ( m \frac{2 π}{N} Δ n )$$

calculated with the absolute value of Δn set to ‘1’ may be previously stored and, upon calculating the Fourier series according to reference point correction, be used.

In other words, the Fourier transform unit 30 performs the Fourier transform process only once, and the Fourier coefficient obtained by the Fourier transform is updated by Equation 6 according to the reference point correction, obtaining the Fourier coefficient according to the correction of the reference point. Thus, computational load may be significantly reduced.

As such, if the characteristic pattern of the resistive leakage current I_{R} is shown in the sum of the sine terms of the Fourier series while performing the reference point verification step S40 according to the Fourier coefficient updated as the reference point is corrected, the sum of the sine terms of the Fourier series finally updated is determined to be the resistive leakage current I_{R} (S60).

Of course, to obtain the resistive leakage current I_{R} in the total leakage current I_{T} in the next period, the process is restarted from the leakage current detection step S10, so that the resistive leakage current I_{R} may be continuously obtained per period. Further, since the resistive leakage current I_{R} continuously obtained may be expressed as the Fourier coefficient of the sine term, only the Fourier coefficients of the sine terms are stored, and they may be continuously obtained. To obtain information on the capacitive leakage current I_{C}, the Fourier coefficients of the cosine terms may be stored together.

Meanwhile, the reference point finally corrected for each period is transmitted to the reference point search unit 20 so that the reference point to be stored and used in the correction unit 21 is updated. Accordingly, as described above, the correction unit 21 may correct the reference point searched for in the current one-period total leakage current I_{T} according to the corrected reference point for the previous one period.

While the inventive concept has been shown and described with reference to exemplary embodiments thereof, it will be apparent to those of ordinary skill in the art that various changes in form and detail may be made thereto without departing from the spirit and scope of the inventive concept as defined by the following claims. Therefore, such modifications should be regarded as belonging to the scope of the present invention, and the scope of the present invention should be determined by the claims to be described later.

### DESCRIPTION OF SYMBOLS

| | |
|---|---|
| 1: surge arrester | 2: grid bus |
| 3: earth ground wire | 10: leakage current |
| 20: reference point search unit | detection unit |
| 30: Fourier transform unit | 11: current transformer |
| 40; resistive leakage current | 12: A/D converter |
| extraction unit | 21: correction unit |
| 41: verification unit | 42: correction unit |
| I_{T}: total leakage current | I_{R}: resistive leakage current |
| I_{c}: capacitive leakage current | u: voltage |

1. A method for detecting a surge arrester resistive leakage current, the method comprising: a leakage current detection step S10 of detecting a total leakage current I_{T} flowing through a surge arrester 1 to which a periodic AC voltage is applied, as a digital data value;
a reference point search step S20 of selecting a time when the total leakage current I_{T} has a highest left-right symmetry, as a reference point;
a Fourier transform step S30 of obtaining a Fourier series by Fourier-transforming the total leakage current I_{T} during one period starting at the reference point;
a reference point verification step S40 of verifying the reference point depending on whether a characteristic pattern of a resistive leakage current I_{R} according to a non-linear resistive characteristic of the surge arrester 1 is shown in a sum of sine terms of the Fourier series;
a reference point correction step S50 of reperforming the reference point verification step S40 by correcting the reference point, if the characteristic pattern is not shown in the reference point verification step S40, and obtaining a Fourier series of the one-period total leakage current I_{T} varying according to reference point correction from an equation resultant from reference point time-shifting a Fourier series before the reference point correction; and
a resistive leakage current extracting step S60 of setting the sum of the sine terms of the Fourier series as the resistive leakage current I_{R} if the characteristic pattern is shown in the reference point verification step S40.

2. The method of claim 1, wherein the reference point correction step S50 sets a sine term coefficient of the Fourier series according to the reference point time shift as
$$- {a}_{m} sin ( m \frac{2 π}{N} Δ n ) + {b}_{m} cos ( m \frac{2 π}{N} Δ n )$$
and a cosine term coefficient as
$${a}_{m} cos ( m \frac{2 π}{N} Δ n ) + {b}_{m} sin ( m \frac{2 π}{N} Δ n ) ,$$
and wherein m is an order of the Fourier coefficient, aₘ is an mth-order cosine term Fourier coefficient of the Fourier series before time shifting, bₘ is an m-order sine term Fourier coefficient of the Fourier series before time shifting, N is a number of samples in one period, and Δn is a sample interval resultant from time-shifting the reference point.

3. The method of claim 1, wherein the reference point search step S20 selects the reference point by modifying one of a reference point searched in a positive (+) period of the one-period total leakage current I_{T} and a reference point searched in a negative (−) period depending on an interval between the two reference points.

4. The method of claim 1, wherein the resistive leakage current I_{R} is continuously obtained for each period, and wherein the reference point search step S20 is able to correct a reference point of a current period depending on an interval between the reference point searched in the current period and a reference point verified by the reference point verification step (S40) in a prior period.

5. The method of claim 4, wherein the reference point search step S20 searches for the reference point of the current period in a predetermined period with respect to a time that is one period after the reference point verified by the reference point verification step S40 in the prior period.

6. A device for detecting a surge arrester resistive leakage current, comprising:
a leakage current detection unit 10 sampling a total leakage current I_{T} flowing through a surge arrester 1 to which a periodic AC voltage is applied, and detecting a digital data value;
a reference point search unit 20 selecting a time when the total leakage current I_{T} has a highest left-right symmetry, as a reference point;
a Fourier transform unit 30 obtaining a Fourier series by Fourier-transforming the total leakage current I_{T} during one period starting at the reference point; and
a resistive leakage current extraction unit 40 correcting the reference point until a characteristic pattern of a resistive leakage current I_{R} according to a non-linear resistive characteristic of the surge arrester 1 is shown in a sum of sine terms of the Fourier series, obtaining the Fourier series of the one-period total leakage current I_{T} varying according to the reference point correction from a Fourier series before the reference point correction, and setting the sum of the sine terms of the Fourier series, where the characteristic pattern of the resistive leakage current I_{R} is shown, as the resistive leakage current I_{R}.

7. The device of claim 6, wherein the resistive leakage current extraction unit 40 sets a sine term coefficient of the Fourier series according to the reference point time shift as
$$- {a}_{m} sin ( m \frac{2 π}{N} Δ n ) + {b}_{m} cos ( m \frac{2 π}{N} Δ n )$$
and a cosine term coefficient as
$${a}_{m} cos ( m \frac{2 π}{N} Δ n ) + {b}_{m} sin ( m \frac{2 π}{N} Δ n ) ,$$
and wherein m is an order of the Fourier coefficient, aₘ is an mth-order cosine term Fourier coefficient of the Fourier series before time shifting, bₘ is an m-order sine term Fourier coefficient of the Fourier series before time shifting, N is a number of samples in one period, and Δn is a sample interval resultant from time-shifting the reference point.

8. The device of claim 6, wherein the reference point search unit 20 selects the reference point by modifying one of a reference point searched in a positive (+) period of the one-period total leakage current I_{T} and a reference point searched in a negative (−) period depending on an interval between the two reference points.

9. The device of claim 6, wherein the resistive leakage current I_{R} is continuously obtained for each period, and wherein the reference point search unit 20 is able to correct a reference point of a current period depending on an interval between the reference point searched in the current period and a reference point corrected by the resistive leakage current extraction unit 40 in a prior period.

10. The device of claim 9, wherein the reference point search unit 20 searches for the reference point of the current period in a predetermined period with respect to a time that is one period after the reference point corrected by the resistive leakage current extraction unit 40 in the prior period.
